(19) United States
(12) Patent Application Publication
(10) Pub. No.: US 2025/0107422 A1
(43) Pub. Date: Mar. 27, 2025

(54) METHOD OF BANDGAP TUNING OF CO-EVAPORATED PEROVSKITE

(71) Applicant: NANYANG TECHNOLOGICAL UNIVERSITY, Singapore (SG)

(72) Inventors: Annalisa BRUNO, Singapore (SG); Herlina Arianita DEWI, Singapore (SG); Subodh Gautam MHAISALKAR, Singapore (SG); Nripan MATHEWS, Singapore (SG)

(21) Appl. No.: 18/291,156

(22) PCT Filed: Jul. 22, 2022
(86) PCT No.: PCT/SG2022/050526

§ 371 Date: Jan. 22, 2024

(30) Foreign Application Priority Data
Jul. 22, 2021 (SG) 10202108002S

(51) Int. Cl. H10K 71/15; H10K 30/10; H10K 30/50

(52) U.S. Cl. CPC H10K 71/15; H10K 30/10; H10K 30/50

(57) ABSTRACT

A method of bandgap tuning of co-evaporated perovskite by a solution process is provided. The method may include providing a co-evaporated perovskite, and treating a surface of the co-evaporated perovskite with a halide-based solution to diffuse the halide-based solution into the co-evaporated perovskite thereby doping it with a halide dopant to form a doped co-evaporated perovskite, wherein the doped co-evaporated perovskite has a characteristic bandgap that is shifted towards a smaller wavelength as compared to the characteristic bandgap of the co-evaporated perovskite before the doping. A doped co-evaporated perovskite having a tuned bandgap, and a solar cell including the doped co-evaporated perovskite is also provided.

### CROSS-REFERENCE TO RELATED APPLICATION

This application claims the benefit of priority of Singapore patent application Ser. No. 10202108002S, filed 22 Jul. 2021, the content of which is incorporated herein by reference in its entirety for all purposes.

### TECHNICAL FIELD

Various embodiments refer to a method of bandgap tuning of co-evaporated perovskite by a solution process forming a doped co-evaporated perovskite having a tuned bandgap, a doped co-evaporated perovskite having a tuned bandgap, and a solar cell (SC) comprising the doped co-evaporated perovskite.

### BACKGROUND

Rapid development of single-junction perovskite solar cells (PSCs) reaching record power conversion efficiency (PCE) as high as 25.7% over small areas (<<1 cm²) and well above 19% for mini-modules have driven worldwide commercialization interests in the last few years. The extraordinary properties of perovskites, such as low fabrication costs, high defect tolerance, long diffusion length, high absorption coefficient, and efficient charge transfer further underline the great promise of perovskite-based optoelectronic devices.

An attractive property lies in the bandgap tunability of perovskites, enabling multi-junction solar cells in combination with low bandgap SC as sub-solar cells, such as solar cells made from silicon, copper indium gallium selenide (CIGS), organic photovoltaic, or even another lower bandgap perovskite. By combining the sub-solar cells in a tandem configuration, an increase in power conversion efficiencies beyond each single-junction solar cells limit may be achieved. In the tandem configuration, the top PSCs mainly utilize the UV-visible part of the solar spectrum and transmit the infrared components to be harvested by underlying lower bandgap sub-solar cells. To make it more feasible for tandem application, perovskite top cell bandgap tuning in the range between 1.66 eV to 1.85 eV is often necessary to optimally utilize the solar spectrum.

One method to obtain a higher-bandgap perovskite is by employing compositions with mixed iodide/bromide halides, possibly in combination with the introduction of multiple cations. In solution-processed perovskites, these higher-bandgap perovskites may be obtained by varying compositions of precursors in solution.

Aside from solution-based processes, perovskites may also be fabricated based on vacuum processes such as thermal evaporation. Fabrication of higher-bandgap evaporated perovskite normally requires multiple co-evaporation sources. Complex co-evaporation to obtain systems combining multi-cation (by incorporation of cesium and formamidinium), as well as multi-halide (iodine and bromine) compositions, may be used to improve perovskite phase stability. Despite successful development of large bandgap perovskites by a complex co-evaporation process, main challenges in adopting these approaches relate to instrumental and operational limitations due to complexity of the multi-source operations. Indeed, availability of dedicated multi-sources thermal evaporators is often limited, and proper control of individual precursor rate to obtain perovskites with phase-stable multi-halide compositions is complex.

In view of the above, there remains a need for an improved method of bandgap tuning of co-evaporated perovskites that overcomes or at least alleviates one or more of the above-mentioned problems.

### SUMMARY

In a first aspect, there is provided a method of bandgap tuning of co-evaporated perovskite by a solution process. The method comprises providing a co-evaporated perovskite, and treating a surface of the co-evaporated perovskite with a halide-based solution to diffuse the halide-based solution into the co-evaporated perovskite thereby doping it with a halide dopant to form a doped co-evaporated perovskite. The doped co-evaporated perovskite has a characteristic bandgap that is shifted towards a smaller wavelength as compared to the characteristic bandgap of the co-evaporated perovskite before the doping.

In a second aspect, there is provided a doped co-evaporated perovskite having a tuned bandgap prepared by a method according to the first aspect.

In a third aspect, a doped co-evaporated perovskite having a tuned bandgap is provided. The doped co-evaporated perovskite comprises a co-evaporated perovskite doped with a halide dopant, wherein the doped co-evaporated perovskite has a characteristic bandgap that is shifted towards a smaller wavelength as compared to the characteristic bandgap of the co-evaporated perovskite without the halide dopant.

In a fourth aspect, a solar cell is provided. The solar cell comprises a doped co-evaporated perovskite having a tuned bandgap prepared by a method according to the first aspect or according to the second or third aspect; one or more charge transport layers on a first side of the doped co-evaporated perovskite having a tuned bandgap; one or more charge transport layers on a second side of the doped co-evaporated perovskite having a tuned bandgap opposite the first side; a first electrode in electrical connection with the one or more charge transport layers; and a second electrode in electrical connection with the one or more charge transport layers.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1A shows a schematic workflow of a hybrid process for bandgap tuning of co-evaporated methylammonium lead iodide perovskite doped with methylammonium bromide (MAPbI₃+MABr) according to an embodiment. As shown in the figure, Step 1 of the hybrid process involves co-evaporating methylammonium iodide (MAI) powder and lead iodide (PbI₂) powder to obtain a methylammonium lead iodide (MAPbI₃) film. In Step 2, methylammonium bromide (MABr) powder is dissolved in anhydrous isopropanol (IPA) to form a MABr solution, which is then dripped onto the MAPbI₃ film. The MAPbI₃ film thereby acts as a template for subsequent deposition of the MABr solution. Treatment of the MABr solution with the MAPbI₃ film is allowed to take place from 1 to 5 minutes. In Step 3, treatment of the MABr solution with the MAPbI₃ film results in formation of a bromide-doped methylammonium lead iodide perovskite (MAPb(BrₓI₁₋ₓ) ₃) film. Excess MABr solution is removed by spin-coating the MAPb(BrₓI₁₋ₓ)₃ film.

FIG. 1B shows photographs of films of the as-deposited MAPbI₃ (0 min), MAPbI₃+MABr sample with 1 minute reaction time (1 min), and MAPbI₃+MABr sample with 5 minutes reaction time (5 min). A negligible color change was observed for the MAPbI₃ film treated for 1 minute with MABr, while prolonged exposure to MABr solution for 5 minutes resulted in a poor film morphology with pinhole formation, and an obvious orange colour appearance on the side of the film.

FIG. 1C shows absorbance vs wavelength (nm) plot for films of (i) as-deposited MAPbI₃ (0 min), (ii) MAPbI₃+MABr sample with 1 min reaction time (1 min), and (iii) MAPbI₃+MABr sample with 5 min reaction time (5 min). As shown in the figure, successful bandgap tuning is demonstrated in the clear shift in absorbance toward lower wavelengths of the MABr-treated films as compared to the pure MAPbI₃.

FIG. 1D shows Tauc plot for films of (i) as-deposited MAPbI₃ (0 min), (ii) MAPbI₃+MABr sample with 1 min reaction time (1 min), and (iii) MAPbI₃+MABr sample with 5 min reaction time (5 min). The MAPbI₃ film has a bandgap of about 1.60 eV, while the MABr-treated films showed bandgaps of about 1.66 eV and about 1.70 eV for 1 minute and 5 minutes treatment, respectively.

FIG. 1E shows steady-state photoluminescence for films of (i) as-deposited MAPbI₃ (0 min), (ii) MAPbI₃+MABr sample with 1 min reaction time (1 min), and (iii) MAPbI₃+MABr sample with 5 min reaction time (5 min). Consistent with the shifts in absorption, shifts of 25 and 50 nm in steady-state photoluminescence peaks were measured for both the (ii) 1 min and (iii) 5 mins MABr-treated films, as compared to the peak for (i) MAPbI₃ film.

FIG. 1F shows normalized X-ray diffraction (XRD) spectra using an incident angle of 2° for films of (i) as-deposited MAPbI₃ (0 min), (ii) MAPbI₃+MABr sample with 1 min reaction time (1 min), and (iii) MAPbI₃+MABr sample with 5 min reaction time (5 min). The 3 vertical dotted lines (from left to right direction) represent (a) PbI₂ <001>, (b) perovskite <110>, and (c) perovskite <202> peak positions for MAPbI₃. The XRD patterns are normalized toward the highest intensity XRD peak for each condition.

FIG. 2A shows XRD patterns of MAPbI₃ film with the incident angle of (i) 8°, (ii) 5°, and (iii) 2°. The graph reveals the formation of compositional gradient as shown by richer PbI₂ content toward the surface. PbI₂ <001> is defined by *. The XRD patterns are normalized toward the highest intensity XRD peak for each condition at the <202> peak

FIG. 2B shows XRD patterns of MAPb(Br_{0.18}I_{0.82})₃ film with the incident angle of (i) 8°, (ii) 5°, and (iii) 2°. The graph reveals the formation of compositional gradient as shown by richer PbI₂ content toward the surface. PbI₂ <001> is defined by *. The XRD patterns are normalized toward the highest intensity XRD peak for each condition at the <202> peak.

FIG. 2C shows zoomed-in XRD peaks at the <202> perovskite peak taken from 24° to 25.2° range for MAPbI₃. Position of the <202> peak does not shift throughout the thickness for MAPbI₃.

FIG. 2D shows zoomed-in XRD peaks at the <202> perovskite peak taken from 24° to 25.2° range for MAPb(Br_{0.18}I_{0.82})₃. The <202> peak gradually shifts from 24.7° into 24.6°, upon increasing the incident angle from 2° to a higher angle of 5° or 8°, suggesting the presence of a bromine gradient with higher bromine content located near perovskite surface.

FIG. 3A shows MAPbI₃ top view Field Emission Scanning Electron Microscopy (FESEM) image with grain size distribution histogram. A film morphology with small, uniform, and compact perovskite grain sizes and narrow distribution with an average size of 150 nm is shown.

FIG. 3B shows MAPbI₃ cross-section FESEM image. A uniform perovskite grain size is shown throughout the whole thickness for the pure MAPbI₃.

FIG. 3C shows MAPb(Br_{0.18}I_{0.82})₃ top view FESEM image with grain size distribution histogram. A film morphology with larger and more inhomogeneous grain sizes upon adopting the bromine halide inside the lattice is shown. The size distribution is wider and the mean grain size is around 250 nm.

FIG. 3D shows MAPb(Br_{0.18}I_{0.82})₃ cross-section FESEM image. There is grain growth from the bottom to the top of the perovskite section, indicating existence of a compositional gradient with a major bromine inclusion on the top of the perovskite film.

FIG. 4A shows absorbance spectra of MAPbI₃ film under continuous 1 sun illumination from 0 s to 3600 s as a measure of light stability.

FIG. 4B shows photoluminescence spectra of MAPbI₃ film under continuous 1 sun illumination from 0 s to 3600 s as a measure of light stability.

FIG. 4C shows absorbance spectra of MAPb(Br_{0.18}I_{0.82})₃ film under continuous 1 sun illumination from 0 s to 3600 s as a measure of light stability.

FIG. 4D shows photoluminescence spectra of MAPb(Br_{0.18}I_{0.82})₃ film under continuous 1 sun illumination from 0 s to 3600 s as a measure of light stability.

FIG. 5A shows a schematic diagram of n-i-p perovskite solar cell with Spiro-OMeTAD as hole transport material (HTM), bilayer tin oxide/[6,6]-phenyl C61 butyric acid methyl ester (SnO₂/PCBM) as electron transport material (ETM) and a gold top contact.

FIG. 5B shows normalized external quantum efficiency (EQE) vs wavelength (nm) of the n-i-p perovskite solar cell shown in FIG. 5A using perovskite material of (i) MAPbI₃ and (ii) MAPb(Br_{0.18}I_{0.82})₃. The band edge of the EQE shifted towards lower wavelengths (about 30 nm), indicating successful bandgap tuning.

FIG. 5C shows Voc of the n-i-p perovskite solar cell shown in FIG. 5A using perovskite material of MAPbI₃ and MAPb(Br_{0.18}I_{0.82})₃.

FIG. 5D shows a schematic diagram of n-i-p perovskite solar cells with poly(triaryl amine) (PTAA) as hole transport material (HTM), bilayer SnO₂/PCBM as electron transport material (ETM) and a gold top contact.

FIG. 5E shows normalized external quantum efficiency (EQE) vs wavelength (nm) of the n-i-p perovskite solar cell shown in FIG. 5D using perovskite material of (i) MAPbI₃ and (ii) MAPb(Br_{0.18}I_{0.82})₃.

FIG. 5F shows V_{oc} of the n-i-p perovskite solar cell shown in FIG. 5D using perovskite material of MAPbI₃ and MAPb(Br_{0.18}I_{0.82})₃.

FIG. 6A shows cross-sectional FESEM of MAPbI₃ on textured silicon.

FIG. 6B shows cross-sectional FESEM (magnified view) of MAPbI₃ on textured silicon.

FIG. 6C shows cross-sectional FESEM of MAPb(Br_{0.18}I_{0.82})₃ on textured silicon.

FIG. 6D shows cross-sectional FESEM (magnified view) of MAPb(Br_{0.18}I_{0.82})₃ on textured silicon.

FIG. 6E shows XRD of MAPbI₃ and MAPb(Br_{0.18}I_{0.82})₃ deposited on textured silicon surface with a pyramidal height of about 5 μm. The XRD patterns are normalized toward the highest intensity XRD peak for each condition. The (a) and (b) vertical dotted lines represent perovskite orientation at <110> and <202> for MAPbI₃, respectively, while the * represents excess PbI₂ in the MAPbI₃.

FIG. 6F shows steady-state photoluminescence of MAPbI₃ and MAPb(Br_{0.18}I_{0.82})₃ deposited on textured silicon surface with a pyramidal height of about 5 μm.

FIG. 7A shows absorbance of (i) MAPbI₃, and MAPbI₃+MABr, whereby the MAPbI₃ was treated with various MABr concentrations of (ii) 5 mg/mL, (iii) 10 mg/mL, and (iv) 15 mg/mL.

FIG. 7B shows absorbance of (i) MAPbI₃, and MAPb(Br_{0.18}I_{0.82})₃ (ii) with and (iii) without post-annealing at 100° C. for 30 mins.

FIG. 8 shows XRD patterns of MAPbI₃, MAPbI₃+MAI, and MAPbI₃+MABr treated for 1 minute. The <110> perovskite peak is indicated by line (a) and <202> perovskite peak is indicated by line (b) for MAPbI₃.

FIG. 9A shows short-circuit current density (J_{sc}) for n-i-p PSCs based on Spiro-OMeTAD as hole transport material (HTM), for MAPbI₃ and MAPb(Br_{0.18}I_{0.82})₃.

FIG. 9B shows fill factor (FF) for n-i-p PSCs based on Spiro-OMeTAD as hole transport material (HTM), for MAPbI₃ and MAPb(Br_{0.18}I_{0.82})₃.

FIG. 9C shows power conversion efficiency (PCE) (%) for n-i-p PSCs based on Spiro-OMeTAD as hole transport material (HTM), for MAPbI₃ and MAPb(Br_{0.18}I_{0.82})₃.

FIG. 10 shows champion perovskite solar cells (PSCs) J-V curves for (i) MAPbI₃ and (ii) MAPb(Br_{0.18}I_{0.82})₃ based PSCs using Spiro-OMeTAD as hole transport material (HTM).

FIG. 11A shows J_{sc} for n-i-p PSCs based on PTAA as hole transport material (HTM), for MAPbI₃ and MAPb(Br_{0.18}I_{0.82})₃.

FIG. 11B shows FF for n-i-p PSCs based on PTAA as hole transport material (HTM), for MAPbI₃ and MAPb(Br_{0.18}I_{0.82})₃.

FIG. 11C shows PCE for n-i-p PSCs based on PTAA as hole transport material (HTM), for MAPbI₃ and MAPb(Br_{0.18}I_{0.82})₃.

FIG. 12 shows champion PSCs J-V curves for (i) MAPbI₃ and (ii) MAPb(Br_{0.18}I_{0.82})₃ based PSCs using PTAA as hole transport material (HTM).

FIG. 13A shows top view FESEM of MAPbI₃ deposited on a textured silicon surface.

FIG. 13B shows top view FESEM of MAPb(Br_{0.18}I_{0.82})₃ deposited on a textured silicon surface.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Advantageously, methods disclosed herein may be used to tune bandgap of a co-evaporated perovskite without requiring a change or adjustment to the co-evaporation processing conditions. In other words, methods disclosed herein may be carried out on a co-evaporated perovskite prepared using conventional equipment. Using a solution process, involving treatment of the co-evaporated perovskite with a halide-based solution, the co-evaporated perovskite may be doped with a halide dopant to form a doped co-evaporated perovskite. The treatment time may be varied to control the extent at which bandgap of the co-evaporated perovskite is adjusted. In so doing, the doped co-evaporated perovskite is able to achieve a tunable bandgap, whereby characteristic bandgap of the doped co-evaporated perovskite may be shifted towards a smaller wavelength as compared to the characteristic bandgap of the co-evaporated perovskite before the doping. This may also result in widening of the bandgap of the co-evaporated perovskite, since bandgap of the doped co-evaporated perovskite may be greater, hence of a wider range, than before.

Advantageously, methods disclosed herein may be particularly useful for forming conformal coatings of high bandgap perovskite on textured surfaces. Uniformity in the perovskite film being formed may mean that methods disclosed herein are suitable for large- area module production. The bandgap tuning may be carried out without modification to existing co-evaporating equipment or processing conditions to include multiple evaporation sources. Furthermore, the doped co-evaporated perovskite obtained have been shown to be stable under illumination, thereby rendering its suitability for use in solar cells.

With the above in mind, various embodiments refer in a first aspect to a method of bandgap tuning of co-evaporated perovskite by a solution process.

The terms “bandgap” and “band gap” are used interchangeably herein, and refer to the energy difference between top of the valence band and bottom of the conduction band of a material. By the term “bandgap tuning”, this means manipulating, adjusting or controlling this energy difference to achieve a desired energy difference or bandgap depending on intended application of the material to achieve optimal performance.

The method comprises providing a co-evaporated perovskite. The term “co-evaporated perovskite” as used herein refers to perovskite obtained or fabricated from simultaneous evaporation of two or more precursor compounds provided in a processing chamber, with subsequent mixing and reacting of the evaporated precursor compounds in the vapor phase to form the co-evaporated perovskite. Advantageously, in using co-evaporation to obtain the co-evaporated perovskite, a solvent-free and low temperature thermal evaporation process may be used, which is scalable and cost-effective. Of particular interest is its capability to conformally coat textured surfaces. These features are important for manufacturing of large-area perovskite, modules, and monolithic tandem solar cells fabrication.

The co-evaporated perovskite may be a doped or undoped co-evaporated perovskite. In various embodiments, the co-evaporated perovskite is an undoped co-evaporated perovskite. For avoidance of doubt, the term “co-evaporated perovskite” does not include perovskite made from solution processing methods, such as spin coating and/or methods involving reaction of precursor compounds in solution.

In various embodiments, providing the co-evaporated perovskite comprises co-evaporating a first precursor compound and a second precursor compound to form their respective vapours in the presence of a substrate, and allowing the vapours to react so as to form a conformal coating of the co-evaporated perovskite on the substrate.

The first precursor compound may, for example, be selected from the group consisting of methylammonium iodide, formamidinium iodide, cesium iodide, rubidium iodide, guanidinium (GA⁺) iodide, and phenethylammonium iodide.

In some embodiments, the first precursor compound comprises methylammonium iodide. In specific embodiments, the first precursor compound is methylammonium iodide.

The second precursor compound may comprise or consist of lead iodide. In specific embodiments, the second precursor compound is lead iodide.

Accordingly, the co-evaporated perovskite may be formed from co-evaporation of one or more of a first precursor compound of methylammonium iodide, formamidinium iodide, cesium iodide, rubidium iodide, guanidinium (GA⁺) iodide, or phenethylammonium iodide, with a second precursor compound of lead iodide.

In various embodiments, the co-evaporated perovskite comprises or consists of methylammonium lead iodide perovskite.

Co-evaporating the first precursor compound and the second precursor compound may be carried out in vacuum or in a solvent free environment. Further, co-evaporating of the first precursor compound and the second precursor compound may be carried out at temperatures which are sufficient to vaporise the first precursor compound and the second precursor compound. Accordingly, the temperatures used may vary depending on the first precursor compound and the second precursor compound that are being used.

In embodiments whereby the first precursor compound is methylammonium iodide, for example, vaporization of the first precursor compound may be carried out at a temperature in the range from about 80° C. to about 150° C., such as about 80° C. to about 130° C., about 80° C. to about 100° C., about 80° C. to about 90° C., about 90° C. to about 130° C., about 115° C. to about 130° C., or about 90° C. to about 110° C.

In embodiments whereby the second precursor compound is lead iodide, for example, vaporization of the second precursor compound may be carried out at a temperature in the range from about 240° C. to about 350° C., such as about 240° C. to about 280° C., about 250° C. to about 280° C., about 260° C. to about 280° C., about 240° C. to about 260° C., about 340° C. to about 350° C., or about 250° C. to about 270° C.

Amounts of the first precursor compound and the second precursor compound in relation to each other are not particularly limited, as it has been found by the inventors that bandgap tuning may be realised with or without excess of the second precursor compound to the first precursor compound. Accordingly, co-evaporating of the first precursor compound and the second precursor compound may be carried out such that vapors of the first and second precursor compounds are in stoichiometric ratio to each other. In some embodiments, co-evaporating of the first precursor compound and the second precursor compound may be carried out to provide vapors of the second precursor compound in excess to that of the first precursor compound.

As mentioned above, co-evaporating of the first precursor compound and the second precursor compound to form their respective vapours is carried out in the presence of a substrate in some embodiments, and allowing the vapours to react so as to form a conformal coating of the co-evaporated perovskite on the substrate.

The method according to embodiments disclosed herein may be used on substrates of any suitable material, choice of which may depend on intended application. Examples of substrate material may include, but not limited to, glass, fluorine-doped tin oxide coated glass (glass/FTO), tin-doped indium oxide coated glass (glass/ITO), silicon, polyethylene naphthalate (PEN).

The substrates may have any suitable surface, such as smooth or textured, rigid or flexible.

In some embodiments, the substrate has a textured surface. Generally, the textured surface of the substrate may comprise structures of any suitable height, such as in the nanometers range, for example, nanostructures having height of about 1 nm to about 100 nm, about 1 nm to about 250 nm, about 1 nm to about 500 nm, or about 100 nm to about 500 nm; or in the micrometres range, for example, microstructures having height of about 1 μm to about 10 μm, about 1 μm to about 100 μm, about 1 μm to about 500 μm, about 1 μm to about 800 μm, or about 100 μm to about 750 μm.

In some embodiments, the textured surface of the substrate comprises structures each having a height in the micrometres range, such as structures each having a height in the range from about 1 μm to about 10 μm. In specific embodiments, the textured surface of the substrate comprises structures each having a height in the range from about 5 μm to about 7 μm.

The structures may be any suitable shape, for example regular shapes such as spherical, hemispherical, conical, and/or pyramidal, or irregular shapes. In some embodiments, the textured surface of the substrate comprises pyramidal structures.

The vapours of the first precursor compound and the second precursor compound may be allowed to react so as to form a conformal coating of the co-evaporated perovskite on the substrate. By the term “conformal”, this means that the coating adheres to and at least substantially covers the substrate. In at least substantially covering the substrate, the conformal coating may form a continuous coating on the substrate. Advantageously, the co-evaporated perovskite may have essentially uniform thickness across the substrate.

The time period for reaction may depend on precursor compounds that are being used and thickness of the co-evaporated perovskite that is to be formed, which may in turn be affected by factors such as base pressure and/or geometry of the processing chamber in which the co-evaporation is carried out, and distance of the precursor compounds to the substrate.

In embodiments for formation of a 750 nm thick perovskite film whereby the first precursor compound is methylammonium iodide and the second precursor compound is lead iodide, for example, reacting of the vapors may be carried out for a time period in the range from about 140 minutes to about 240 minutes, such as about 140 minutes to about 220 minutes, about 160 minutes to about 240 minutes, about 180 minutes to about 240 minutes, about 200 minutes to about 240 minutes, about 140 minutes to about 200 minutes, about 140 minutes to about 180 minutes, about 160 minutes to about 200 minutes, or about 170 minutes to about 190 minutes.

In various embodiments, providing the co-evaporated perovskite further comprises annealing the co-evaporated perovskite. Though not generally required to form the co-evaporated perovskite, the annealing may be carried out in some embodiments to fully form the co-evaporated perovskite depending, for example, on forming stability of the composition. In embodiments whereby the co-evaporated perovskite comprises or consists of formamidinium (FAI)-containing perovskites, annealing the co-evaporated perovskite may generally be carried out. The annealing may be carried out at any suitable temperature and time period depending on the co-evaporated perovskite being used.

For example, when the co-evaporated perovskite is methylammonium lead iodide perovskite, the annealing may be carried out at a temperature in the range from about 80° C. to about 120° C., such as about 90° C. to about 120° C., about 100° C. to about 120° C., about 80° C. to about 110° C., about 80° C. to about 100° C., or about 90° C. to about 110° C., and/or for a time period in the range from about 20 minutes to about 45 minutes, such as about 30 minutes to about 45 minutes, about 20 minutes to about 30 minutes, or about 25 minutes to about 35 minutes.

In various embodiments, thickness of the co-evaporated perovskite may be greater than 300 nm, and up to 1 μm. For example, thickness of the co-evaporated perovskite may be in the range from about 300 nm to about 1 μm, about 300 nm to about 800 nm, about 300 nm to about 750 nm, about 500 nm to about 1 μm, about 600 nm to about 1 μm, about 700 nm to about 800 nm, or about 750 nm. In some embodiments, thickness of the co-evaporated perovskite is about 750 nm.

The co-evaporated perovskite may be treated with a halide-based solution on a surface of the co-evaporated perovskite to diffuse the halide-based solution into the co-evaporated perovskite. In so doing, the co-evaporated perovskite may be doped with a halide dopant to form a doped co-evaporated perovskite.

Examples of halide dopant may include chloride anion, bromide anion, and iodide anion.

Diffusing of the halide-based solution into the co-evaporated perovskite may be aided by gravity. For example, the halide-based solution may be dispersed on a top or side surface of the co-evaporated perovskite, such that in addition to diffusion, the halide-based solution may be drawn into the co-evaporated perovskite via action of gravity.

The halide-based solution may be selected from the group consisting of methylammonium bromide solution and formamidinium bromide solution, which may be prepared by dissolving methylammonium bromide or formamidinium bromide respectively in a suitable solvent such as, but not limited to, anhydrous isopropanol.

In some embodiments, the halide-based solution is methylammonium bromide solution, which may be prepared by dissolving methylammonium bromide in anhydrous isopropanol.

The halide-based solution may have a concentration in the range from about 3 mg/ml to about 15 mg/ml, such as about 5 mg/ml to about 15 mg/ml, about 7 mg/ml to about 15 mg/ml, about 10 mg/ml to about 15 mg/ml, about 12 mg/ml to about 15 mg/ml, about 3 mg/ml to about 12 mg/ml, about 3 mg/ml to about 10 mg/ml, about 3 mg/ml to about 8 mg/ml, about 5 mg/ml to about 10 mg/ml, or about 7 mg/ml to about 12 mg/ml.

In some embodiments, the halide-based solution may be a methylammonium bromide solution having a concentration of about 10 mg/ml.

Treating a surface of the co-evaporated perovskite with the halide-based solution may be carried out for a time period that allows the co-evaporated perovskite to react fully with the halide-based solution. The time period may depend on factors such as amount of bandgap shift to be achieved and thickness of the co-evaporated perovskite film. Generally, the larger the bandgap shift to be achieved, the longer the time period for which the co-evaporated perovskite is being treated with the halide-based solution. When the co-evaporated perovskite is of a larger thickness, a longer time period may be used.

In various embodiments, treating a surface of the co-evaporated perovskite with the halide-based solution is carried out for a time period in the range from about 20 seconds to about 10 minutes, such as about 30 seconds to about 10 minutes, about 1 minute to about 10 minutes, about 3 minutes to about 10 minutes, about 5 minutes to about 10 minutes, about 7 minutes to about 10 minutes, about 20 seconds to about 8 minutes, about 20 seconds to about 5 minutes, about 20 seconds to about 3 minutes, about 20 seconds to about 1 minute, about 1 minute to about 5 minutes, or about 1 minute to about 3 minutes.

In some embodiments, treating a surface of the co-evaporated perovskite with the halide-based solution may comprise controlling the time period at which the treating is carried out to control the extent at which the characteristic bandgap is being shifted. As mentioned above, a longer time period at which the treating is carried out may be used to obtain a larger shift in characteristic bandgap.

In specific embodiments, treating a co-evaporated perovskite with thickness of 500 nm with a halide-based solution for about 30 seconds was found to be sufficient to induce a bandgap shift.

As mentioned above, the co-evaporated perovskite may be treated with a halide-based solution on a surface of the co-evaporated perovskite to diffuse the halide-based solution into the co-evaporated perovskite, so as to dope the co-evaporated perovskite with a halide dopant to form a doped co-evaporated perovskite, the doped co-evaporated perovskite having a characteristic bandgap that is different from the characteristic bandgap of the co-evaporated perovskite before the doping.

Accordingly, methods according to embodiments disclosed herein may be considered to be hybrid methods involving vapour and solution processing, in which vapour processing in the form of co-evaporation is used to form the co-evaporated perovskite, followed by solution processing whereby a halide-based solution is used to treat the co-evaporated perovskite to form a doped co-evaporated perovskite having a tuned bandgap.

The doped co-evaporated perovskite may have a characteristic bandgap that is shifted towards a smaller wavelength as compared to the characteristic bandgap of the co-evaporated perovskite before the doping. In terms of bandgap value, this may mean that the doped co-evaporated perovskite has a higher value as compared to that of the co-evaporated perovskite without the halide dopant. In various embodiments, the co-evaporated perovskite without the halide dopant may have a bandgap of 1.6 eV, which may not be ideal for use in applications such as multi-junction devices. Using a method disclosed herein, bandgap of the doped co-evaporated perovskite may be increased, such as to 1.66 eV or 1.7 eV.

In various embodiments, treating a surface of the co-evaporated perovskite with the halide-based solution further comprises removing excess halide-based solution after diffusion of the halide-based solution into the co-evaporated perovskite has taken place. Removal of excess halide-based solution may advantageously be carried out to prevent changes in composition of the doped co-evaporated perovskite, and/or modification of perovskite morphology and structure due to action of solvent in the halide-based solution, and/or negatively affecting stability of the doped co-evaporated perovskite film should the film be damaged as a result of presence of the excess halide-based solution. The excess halide-based solution may be removed, for example, by spin coating the co-evaporated perovskite to remove residual halide-based solution that may be present on a surface of the doped co-evaporated perovskite.

In various embodiments, treating the co-evaporated perovskite with a halide-based solution on a surface of the co-evaporated perovskite further comprises annealing the doped co-evaporated perovskite. Though not generally required for shifting of the bandgap, the annealing may be carried out in some embodiments to fully form the doped co-evaporated perovskite. In addition to or alternatively, annealing of the doped co-evaporated perovskite may be carried out to remove residual solvent that may be present on the surface of the co-evaporated perovskite. Since annealing does not generally result in shifting of the bandgap, this may translate into greater flexibility when the doped co-evaporated perovskite is being used in formation of devices whereby annealing is being used to form the other interlayers. The annealing may be carried out at any suitable temperature and duration, such as a temperature in the range from about 80° C. to about 120° C., or about 90° C. to about 120° C., about 100° C. to about 120° C., about 80° C. to about 110° C., about 80° C. to about 100° C., or about 90° C. to about 110° C., and/or for a time period in the range from about 20 minutes to about 40 minutes, about 30 minutes to about 40 minutes, about 20 minutes to about 30 minutes, or about 25 minutes to about 35 minutes.

Various embodiments refer in a second aspect to a doped co-evaporated perovskite having a tuned bandgap prepared by a method according to the first aspect, and in a third aspect to a doped co-evaporated perovskite having a tuned bandgap.

By the term “tuned bandgap”, this means that the doped co-evaporated perovskite has a characteristic bandgap that is different as compared to the characteristic bandgap of the co-evaporated perovskite without the halide dopant.

For example, the doped co-evaporated perovskite may have a characteristic bandgap that is shifted towards a smaller wavelength as compared to the characteristic bandgap of the co-evaporated perovskite without the halide dopant. In terms of bandgap value, this may mean that the doped co-evaporated perovskite has a higher value as compared to that of the co-evaporated perovskite without the halide dopant. In various embodiments, the co-evaporated perovskite without the halide dopant may have a bandgap of 1.6 eV. Using a method disclosed herein, bandgap of the doped co-evaporated perovskite may be increased to 1.66 eV or 1.7 eV.

The doped co-evaporated perovskite may comprise a co-evaporated perovskite doped with a halide dopant. Examples of halide dopant may include chloride anion, bromide anion, and iodide anion.

In various embodiments, the halide dopant has a decreasing concentration gradient along a thickness direction from a surface of the doped co-evaporated perovskite. The decreasing concentration gradient may be observed using analytical methods such as XRD. By the term “decreasing concentration gradient”, this means that the halide dopant in the doped co-evaporated perovskite has a concentration gradient from large to small, and/or is decreasing, along a thickness direction from the surface of the doped co-evaporated perovskite. This means that the halide dopant may have highest concentration at a surface region of the doped co-evaporated perovskite, which decreases with increasing depth into the doped co-evaporated perovskite.

The decreasing concentration gradient of the halide dopant in the doped co-evaporated perovskite may translate into the doped co-evaporated perovskite having a decreasing grain size gradient along a thickness direction from the surface of the doped co-evaporated perovskite. By the term “decreasing grain size gradient”, this means that the doped co-evaporated perovskite has a grain size gradient from large to small and/or is made up of grains of a decreasing size along a thickness direction from the surface of the doped co-evaporated perovskite. In other words, grain size of the doped co-evaporated perovskite may be largest at a surface region of the doped co-evaporated perovskite, which decreases with increasing depth into the doped co-evaporated perovskite.

Grain size of the doped co-evaporated perovskite at an inner portion of the doped co-evaporated perovskite may be about 20% to about 50% of that at a surface portion of the doped co-evaporated perovskite. For example, grain size of the doped co-evaporated perovskite at an inner portion of the doped co-evaporated perovskite may be about 30% to about 50%, about 40% to about 50%, about 20% to about 40%, about 20% to about 30%, about 25% to about 45%, or about 30% to about 40% of that at a surface portion of the doped co-evaporated perovskite.

In various embodiments, the doped co-evaporated perovskite has formula AB(PₓQ₁₋ₓ)₃, wherein A represents an organic, inorganic or hybrid cation, B represents a metal cation, P and Q are different halide anions, and x is in the range from about 0.1 to about 0.5.

A may be selected from the group consisting of the group consisting of methylammonium, formamidinium, cesium, rubidium, guanidinium (GA⁺), phenethylammonium. or any of their combinations. In various embodiments, A is methylammonium.

In various embodiments, B is lead cation.

P and Q may be independently selected from the group consisting of chloride anion, bromide anion, and iodide anion.

In various embodiments, P is an iodide anion.

In various embodiments, Q is a bromide anion.

In some embodiments, the doped co-evaporated perovskite has formula CH₃NH₃Pb(Br_{0.18}I_{0.82})₃.

The doped co-evaporated perovskite may be a conformal coating positioned on a substrate. Thickness of the doped co-evaporated perovskite may be greater than 300 nm. For example, thickness of the doped co-evaporated perovskite may be in the range from about 300 nm to about 800 nm, about 300 nm to about 750 nm, about 500 nm to about 800 nm, about 600 nm to about 800 nm, about 700 nm to about 800 nm, or about 750 nm. In some embodiments, thickness of the doped co-evaporated perovskite is about 750 nm.

As mentioned above, the substrate may have a textured surface. Examples of suitable substrates and textured surfaces have already been described above.

In various embodiments, the textured surface of the substrate comprises structures each having a height in the micrometres range, such as structures each having a height in the range from about 1 μm to about 10 μm. In specific embodiments, the textured surface of the substrate comprises structures each having a height in the range from about 5 μm to about 7 μm.

In various embodiments, the textured surface of the substrate comprises pyramidal structures.

In a fourth aspect, a solar cell is provided. The solar cell may comprise a doped co-evaporated perovskite having a tuned bandgap prepared by a method according to the first aspect or according to the second or third aspect; one or more charge transport layers on a first side of the doped co-evaporated perovskite having a tuned bandgap; one or more charge transport layers on a second side of the doped co-evaporated perovskite having a tuned bandgap opposite the first side; a first electrode in electrical connection with the one or more charge transport layers; and a second electrode in electrical connection with the one or more charge transport layers.

Both n-i-p and p-i-n architectures may be used. Accordingly, the charge transport layer may be an electron transport layer or a hole transport layer, depending on whether it is a n-i-p or p-i-n architecture.

For example, in a n-i-p configuration, the solar cell may comprise a doped co-evaporated perovskite having a tuned bandgap as disclosed herein; one or more electron transport layers on a first side of the doped co-evaporated perovskite having a tuned bandgap; one or more hole transport layers on a second side of the doped co-evaporated perovskite having a tuned bandgap opposite the first side; a first electrode in electrical connection with the one or more electron transport layers; and a second electrode in electrical connection with the one or more hole transport layers.

On the other hand, in a p-i-n configuration, the solar cell may comprise a doped co-evaporated perovskite having a tuned bandgap as disclosed herein; one or more hole transport layers on a first side of the doped co-evaporated perovskite having a tuned bandgap; one or more electron transport layers on a second side of the doped co-evaporated perovskite having a tuned bandgap opposite the first side; a first electrode in electrical connection with the one or more hole transport layers; and a second electrode in electrical connection with the one or more electron transport layers.

Advantageously, doping of the co-evaporated perovskite during a method disclosed herein result in bandgap widening which further enhances properties of co-evaporated perovskite solar cells, such as great scalability, intrinsic stability, high-power conversion efficiency, and fabrication adaptability even on rough surfaces.

In order that the invention may be readily understood and put into practical effect, particular embodiments will now be described by way of the following non-limiting examples.

### EXAMPLES

In embodiments disclosed herein, a hybrid two-step method to fabricate wider bandgap perovskites which are effective also for film thicknesses well above 300 nm is presented.

For the first time, a co-evaporated MAPbI₃ film with an excess of PbI₂ as a template and a MABr solution-based treatment to create bromine interdiffusion into the films were used. Bandgap of the co-evaporated MAPbI₃ of about 1.60 eV was tuned to 1.66 eV through the MABr-based treatment, thereby achieving bandgap widening. Advantageously, bandgap of the co-evaporated MAPbI₃ may be widened without any change in the co-evaporation deposition process. Without wishing to be bound by theory, this efficiently tuning of the MAPbI₃ film bandgap may take place by inducing a bromine gradient across the perovskite thickness. By controlling MABr reaction time, bandgap of the co-evaporated MAPbI₃ may be tuned. In the experiments carried out, a stable MAPb(Br_{0.18}I_{0.82})₃ film with a bandgap about 1.66 eV may be obtained by using a co-evaporated MAPbI₃ as a template with a bandgap of about 1.6 eV.

Using MAPbI₃ as an example, the inventors have shown that bromine incorporation can efficiently take place even with a 750 nm thick co-evaporated MAPbI₃ layer with textured surface, as verified with optical, structural, and morphological analysis and demonstrated by the shift in the absorption spectra, photoluminescence, XRD peaks, and the enlargement of the grain sizes. The MABr-treated perovskite composition films (MAPb(Br_{0.18}I_{0.82})₃) demonstrated good spectral stability under continuous 1-sun illumination at ambient conditions of 28° C. and 70% relative humidity.

With these higher-bandgap perovskite films as active layers, n-i-p PSCs clearly showed a blue shift in their external quantum efficiency (EQE) and a significant increase in V_{oc} (up to 30 mV) as compared to the standard of pure MAPbI₃ PSCs, in agreement with the bandgap widening. Methods disclosed herein can be universally applied to MAPbI₃ deposited on both flat and textured surfaces and shows great promise for its integration in monolithic tandems, given the importance of bandgap perovskites in such use.

### Perovskite Absorber

750 nm thick MAPbI₃ films were deposited on glass substrates by co-evaporating PbI₂ powder (TCI) and MAI powder (Lumtec). This thickness was chosen as it is capable of achieving the highest PCE performance in PSCs.

The co-evaporations were carried out using machines from Mantis (UK) and Syskey Technology Co., Ltd., (Taiwan). Generally, the temperature and timing used may depend on the machine and/or the precursors used. For the experimental results disclosed herein, machine from Mantis (UK) was used. The PbI₂ source was fit at 260° C. and the MAI source was set at 100° C. with a total deposition time of 180 mins inside a vacuum chamber with a base starting chamber pressure of 8*10⁻⁶ Torr. Upon deposition, the MAPbI₃ film was subsequently annealed at 100° C. for 30 mins. In some experiments carried out (results not provided herein), machine from Syskey Technology Co., Ltd., (Taiwan) was used. The PbI₂ source was set at temperatures between 340° C. and 350° C., and MAI source set at temperatures between 119° C. and 128° C., with timings in the range between 180 and 240 minutes.

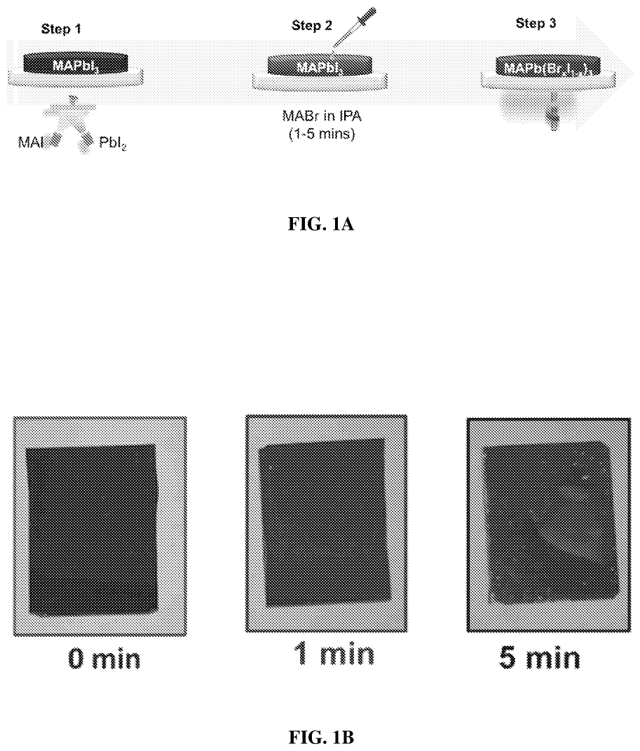

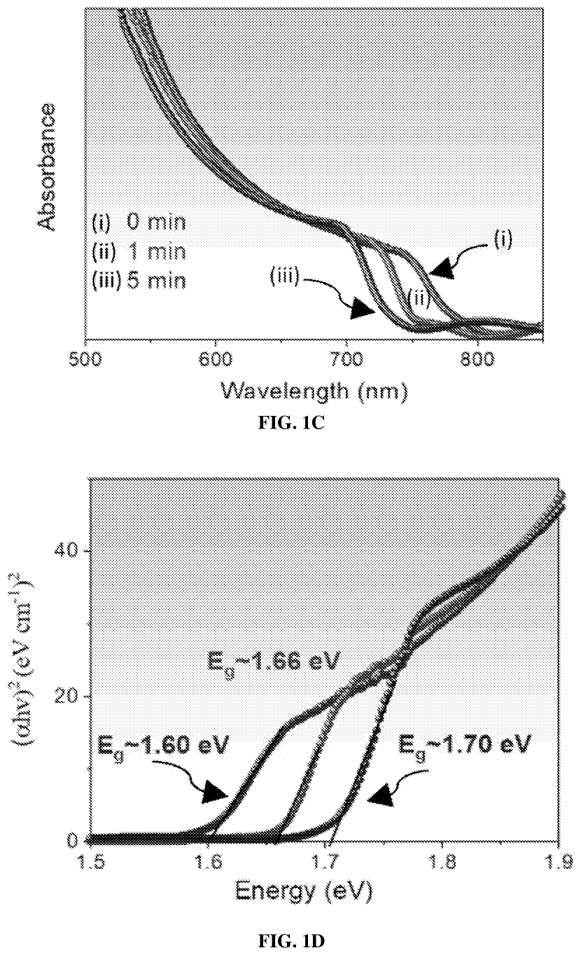

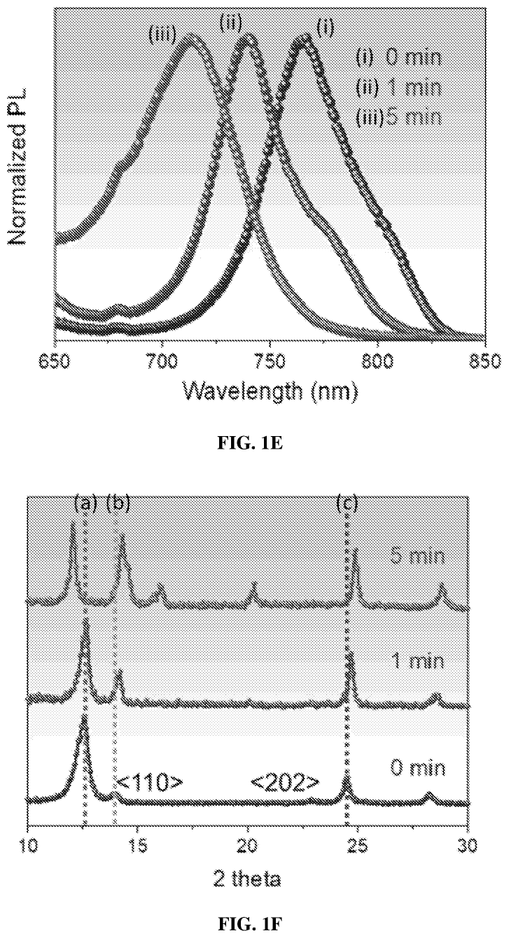

MAPb(BrₓI₁₋ₓ)₃ films was prepared using as-deposited MAPbI₃ as a template. The MABr (Greatcell) was dissolved in anhydrous isopropanol (IPA) with concentrations ranging from 5 to 15 mg/mL. The MAPb(BrₓI₁₋ₓ)₃ films were prepared by dropping the MABr solution (with a concentration of 10 mg/ml in IPA) on the as-deposited MAPbI₃ film and letting it react for a certain time interval (ranging from 1 min to 5 mins) before spin-coating the films at 5000 rpm for 30 s to remove unreacted MABr/IPA and consequently being annealed at 100° C. for 30 mins. The 3-steps process is schematized in FIG. 1A. The specific temperature and pressure used in the co-evaporation process may depend on the specific equipment and precursors used.

The pictures of the films before and after 1 and 5 minutes reaction times are shown in FIG. 1B, labelled as “0 min”, “1 min” and “5 min” respectively. A negligible color change can be observed for the films treated for 1 min with MABr, while prolonged exposure to MABr solution for 5 minutes resulted in a poor film morphology, pinhole formation, and an obvious orange color appearance on the side of the substrate.

FIG. 1C shows absorbance vs wavelength (nm) plot for (i) as-deposited MAPbI₃ (0 min), (ii) MAPbI₃+MABr sample with 1 min reaction time (1 min), and (iii) MAPbI₃+MABr sample with 5 min reaction time (5 min). As shown in the figure, successful bandgap tuning is demonstrated in the clear shift in absorbance toward lower wavelengths of the MABr-treated films as compared to the pure MAPbI₃.

Shift of the bandgap in eV can also be observed from the Tauc plots in FIG. 1D. The MAPbI₃ film has a bandgap of about 1.60 eV, while the MABr-treated films showed bandgaps of about 1.66 eV and about 1.70 eV for 1 minutes and 5 minutes treatment, respectively.

Phase segregation may occur when bromine concentration is above 0.2 to 1 for MAPb(BrₓI₁₋ₓ)₃ composition. Based on the empirical equation: E_{g}(x)=1.57+0.39x+0.33x², where E_{g} is the bandgap of perovskite (in eV) and x is the amount of Br, the hybrid perovskite films compositions are estimated as MAPb(Br_{0.18}I_{0.82})₃ and MAPb(Br_{0.28}I_{0.72})₃ for 1 min and 5 min MABr treatment.

FIG. 1E shows steady-state photoluminescence for (i) as-deposited MAPbI₃ (0 min), (ii) MAPbI₃+MABr sample with 1 min reaction time (1 min), and (iii) MAPbI₃+MABr sample with 5 min reaction time (5 min). Consistent with the shifts in absorption, shifts of 25 and 50 nm in steady-state photoluminescence peaks were measured for both the (ii) 1 min and (iii) 5 mins MABr-treated films, as compared to the peak for (i) MAPbI₃ film.

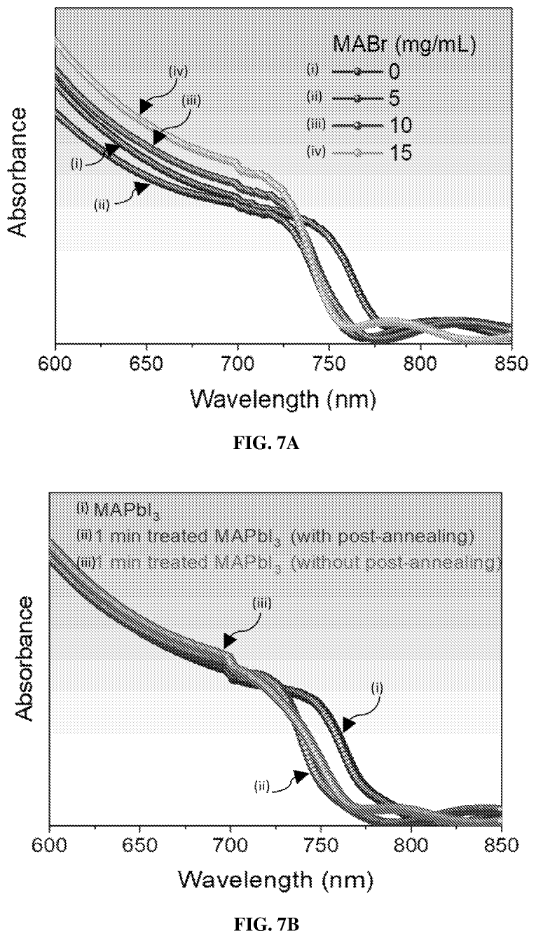

In FIG. 7A, use of different MABr concentrations is shown, ranging from 5 to 15 mg/mL with 1 minute reaction time. It proved that an identical absorption shift (and bandgap) may be achieved regardless of different MABr concentrations. This result highlights that the conversion time may be the crucial parameter to determine the final bandgap in this hybrid method, rather than the MABr concentration.

Effect of the annealing process on the bandgap shift was also investigated. In FIG. 7B, it is shown that a similar absorbance shift may be attained for the 1 min MABr-treated films prepared with and without post-annealing process at 100° C. for 30 minutes, confirming that the interdiffusion process does not require a thermal annealing process to ensure an efficient reaction of excess PbI₂ inside perovskite with the MABr.

FIG. 1F shows normalized XRD using an incident angle of 2° for (i) as-deposited MAPbI₃ (0 min), (ii) MAPbI₃+MABr sample with 1 min reaction time (1 min), and (iii) MAPbI₃+MABr sample with 5 min reaction time (5 min). The 3 vertical dotted lines (from left to right direction) represent (a) PbI₂ <001>, (b) perovskite <110>, and (c) perovskite <202> peak positions for MAPbI₃. The XRD patterns are normalized toward the highest intensity XRD peak for each condition.

As can be seen from the figure, the MAPbI₃ film exhibits two main crystal orientations at <110> and <202> directions, with the latter being more dominant as shown by the sharp perovskite peak at 24.5°, and an excess of PbI₂ <001>, denoted by the 12.5° XRD peak (curve at 0 min in FIG. 1F). The XRD pattern of 1 min MABr-treated films, (curve at 1 min in FIG. 1F), shows few interesting features. First, a significant reduction in the PbI₂ peak suggests that the reaction of MABr with the PbI₂ excess takes place. Furthermore, the <202> perovskite peak shifts from 24.5° to 24.7°, while the <110> perovskite peak becomes more intense and shifts from 14° to 14.2°, as compared to MAPbI₃, confirming the incorporation of bromine into perovskite lattice.

The XRD pattern of 5 min MABr-treated films (5 min curve in FIG. 1F), also exhibits very distinctive features. A full conversion of excess PbI₂ after 5 min MABr treatment is demonstrated from the disappearance of the PbI₂ peak, while both the <110> and <202> orientation become well defined. As compared with the MAPbI₃, the <202> perovskite peak shifts from 24.5° to 24.9° and the <110> perovskite peak becomes broad and shows a shift from 14° to 14.3°. Besides, multiple XRD peaks appeared at 12°, 16°, and 20°, suggesting the formation of additional phases or orientation changes related to bromine excess.

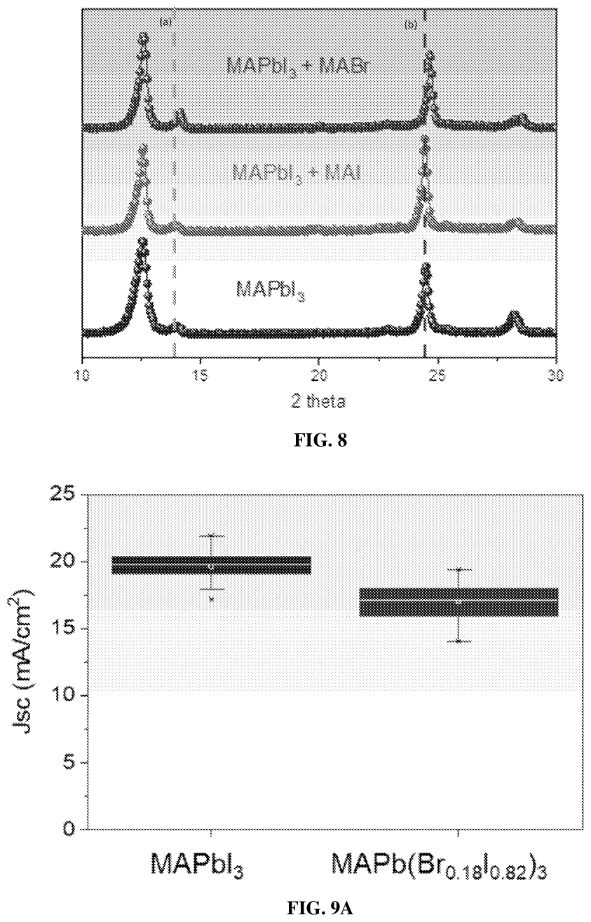

To confirm that the main perovskite XRD peaks shift is caused by presence of bromine halide, the co-evaporated MAPbI₃ film was treated with MAI solution (10 mg/ml MAI in IPA) for 1 minute. The XRD patterns of MAPbI₃, MAPbI₃+MAI, and MAPbI₃+MABr treated for 1 minute are shown in FIG. 8. The <110> perovskite peak is indicated by line (a) and <202> perovskite peak is indicated by line (b) for MAPbI₃.

Referring to FIG. 8, reduction in PbI₂ and higher <202> perovskite peaks were observed for MAPbI₃+MAI as compared to the MAPbI₃ standard, which is similar to that for MABr-treated film. This indicates reaction of MAI with excess PbI₂ inside the film. Indeed, the MAI-treated film shows unshifted peak position for both <110> and <202> perovskite orientations, confirming that the XRD peak shift is driven by bromine inclusion inside perovskite lattice, and not because of the hybrid process.

A combination of poor perovskite film morphology, unstable phase formation due to higher bromine content, and the additional XRD peaks in 5 min MABr-treated films suggest that this condition of 5 min treatment time may not be suitable to reach long-term stability for this embodiment. Hence, subsequent studies are done using the 1 min MABr-treated films, and these are referred to herein as MAPb(Br_{0.18}I_{0.82})₃.

### Iodine/Bromine Ratio across Film Thickness

To assess the iodine/bromine ratio across the whole film thickness for both MAPbI₃ and MAPb(Br_{0.18}I_{0.82})₃, XRD patterns were measured using different incident angles from 2° to 8°. TABLE 1 depicts penetration depth (nm) of X-ray into MAPbI₃ film as a function of incident angle (°). The penetration depth Z was calculated according to the formula,

$$Z = \frac{sin α}{μ} ,$$

where α is the incident angle, μ is the attenuation coefficient (1181.5 cm⁻¹ for MAPbI₃).

TABLE 1

| Incident angle (°) | Penetration depth (nm) |
|---|---|
| 2 | 290 ± 15 |
| 5 | 740 ± 15 |
| 8 | 1200 ± 15 |

As shown in TABLE 1, higher incident angles can indeed probe a deeper portion within the perovskite film.

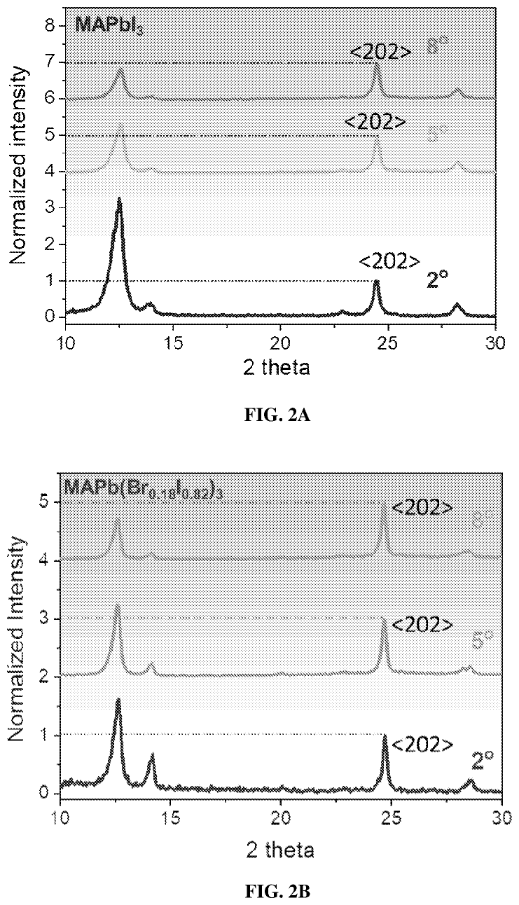

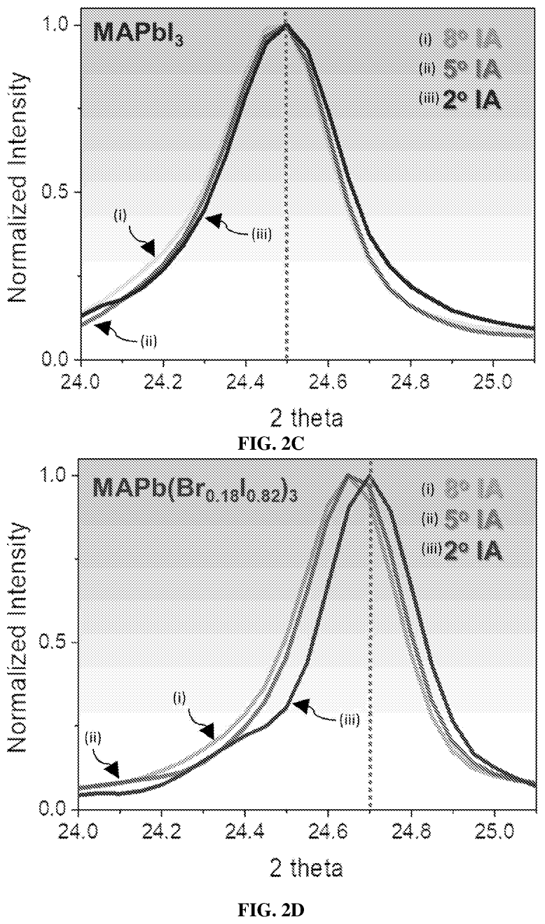

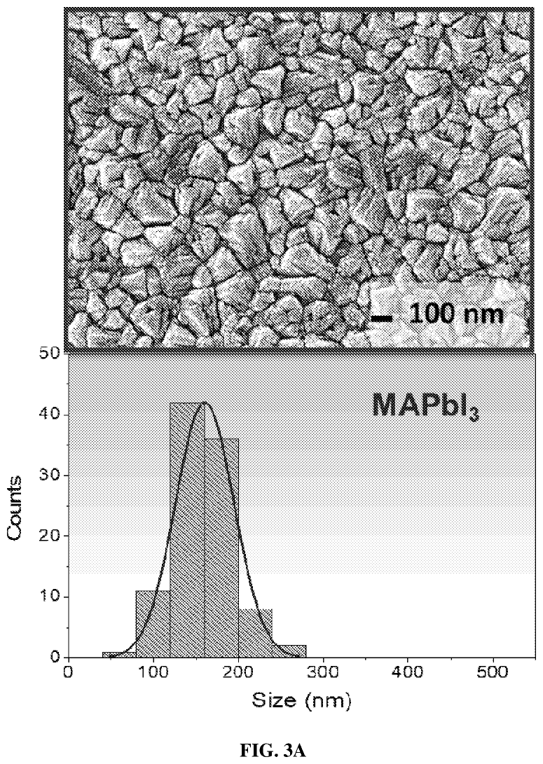

FIG. 2A shows MAPbI₃ XRD patterns with the incident angle of (i) 8°, (ii) 5°, and (iii) 2°. The graph reveals the formation of compositional gradient as shown by richer PbI₂ content toward the surface. The MAPbI₃ film shows, for all incident angles, a dominant <202> perovskite orientation and a noticeable compositional gradient across the whole perovskite thickness, with a higher PbI₂ <001> content, on nearby perovskite surface.

In contrast, the MAPb(Br_{0.18}I_{0.82})₃ film shows a higher <110> peak for all the incident angles as compared to MAPbI₃, as can be seen from FIG. 2B which shows MAPb(Br_{0.18}I_{0.82})₃ XRD patterns with the incident angle of (i) 8°, (ii) 5°, and (iii) 2°. The graph reveals the formation of compositional gradient as shown by richer PbI₂ content toward the surface. Moreover, the <110> peak appears to be more predominant with the lowest incident angle (2°), indicating that even though MABr can inter-diffuse and react with an excess of PbI₂ throughout the whole thickness, the prominent reaction is occurring at the surface.

To monitor the bromine and iodine composition, the dominant perovskite peak at <202> is compared for different incident angles. As a reference, it is shown that as expected the position of the <202> peak does not shift throughout the thickness for MAPbI₃, see e.g. the zoom-in MAPbI₃ XRD patterns in FIG. 2C. On the other hand, the MAPb(Br_{0.18}I_{0.82})₃ XRD patterns in the zoom-in XRD patterns in FIG. 2D show that the <202> peak gradually shifts from 24.7° into 24.6°, upon increasing the incident angle from 2° to a higher angle of 5° or 8°, suggesting the presence of a bromine gradient with higher bromine content located near perovskite surface.

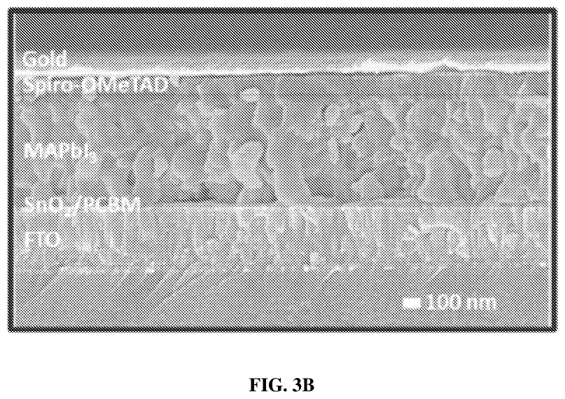

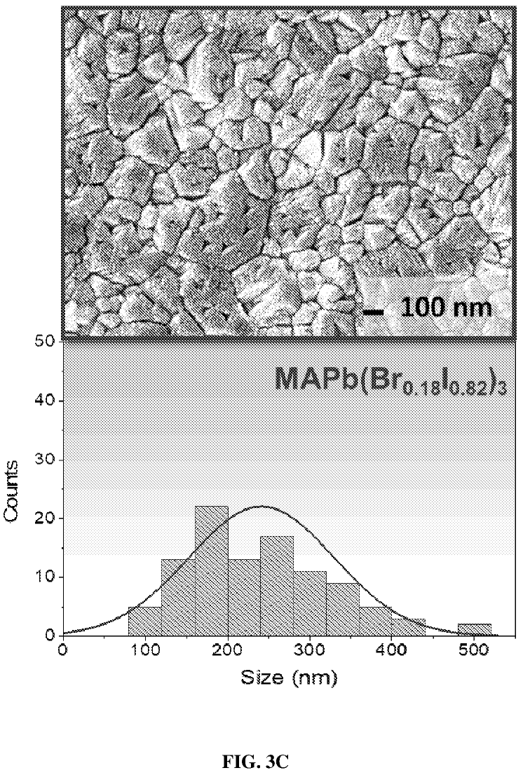

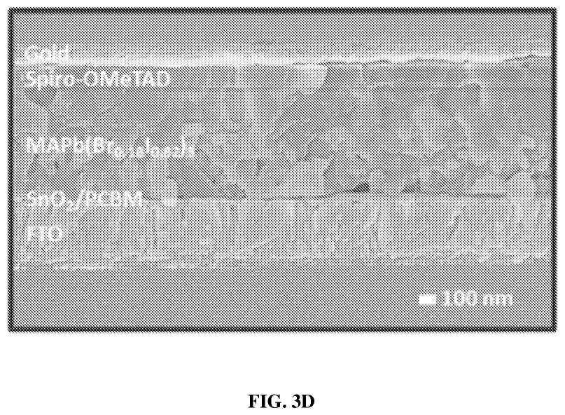

The MAPbI₃ and MAPb(Br_{0.18}I_{0.82})₃ film compositions were also investigated through Field Emission Scanning Electron Microscopy (FESEM) images to correlate the effect of bromine/iodine gradient with the perovskite morphology. The top-view FESEM image of the MAPbI₃ in FIG. 3A shows a film morphology with small, uniform, and compact perovskite grain sizes and narrow distribution with an average size of 150 nm. Also, the cross-section FESEM image in FIG. 3B shows a uniform perovskite grain size throughout the whole thickness for pure MAPbI₃.

While for the MAPb(Br_{0.18}I_{0.82})₃ films, the FESEM top-view image in FIG. 3C shows larger and more inhomogeneous grain sizes upon adopting the bromine halide inside the lattice. The size distribution is wider and the mean grain size around 250 nm. Moreover, a cross-section FESEM image of the perovskite solar cells (PSCs) in FIG. 3D reveals an obvious grain growth from the bottom to the top of the perovskite section. This difference in grain size for MAPb(Br_{0.18}I_{0.82})₃ throughout the whole thickness confirms the existence of a compositional gradient with a major bromine inclusion on the top of the perovskite film, in agreement with the angle dependant XRD results (FIG. 2B). Although presumably, more uniform and bigger grain sizes can be achieved with longer MABr treatment, obtained bandgap of greater than 1.66 eV may be unfavorable in some instances due to phase instability.

### Light-Induced Phase Stability

To monitor the light-induced phase stability of the different compositions, both MAPbI₃ and MAPb(Br_{0.18}I_{0.82})₃ films were exposed to a continuous 1 sun illumination for 1 hour at room temperature, about 27° C., and ambient condition, about 70% relative humidity (RH).

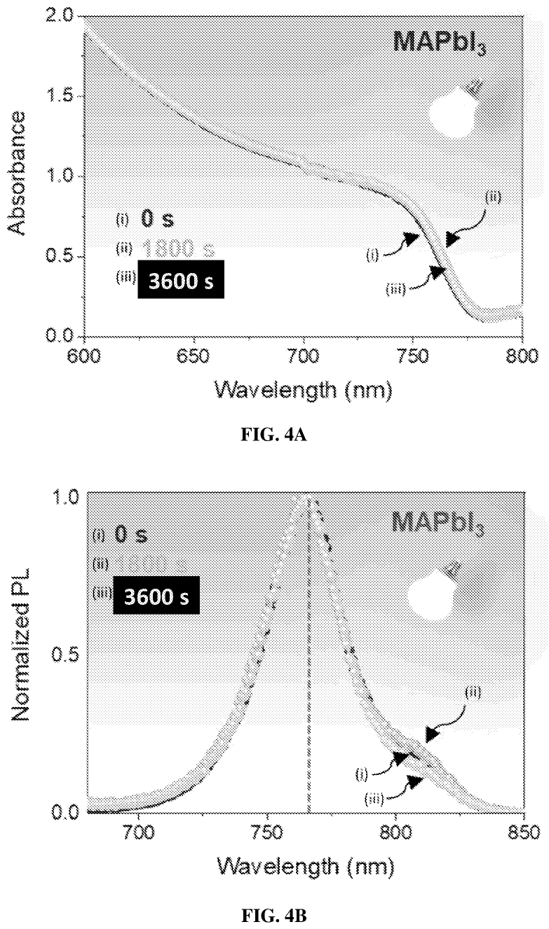

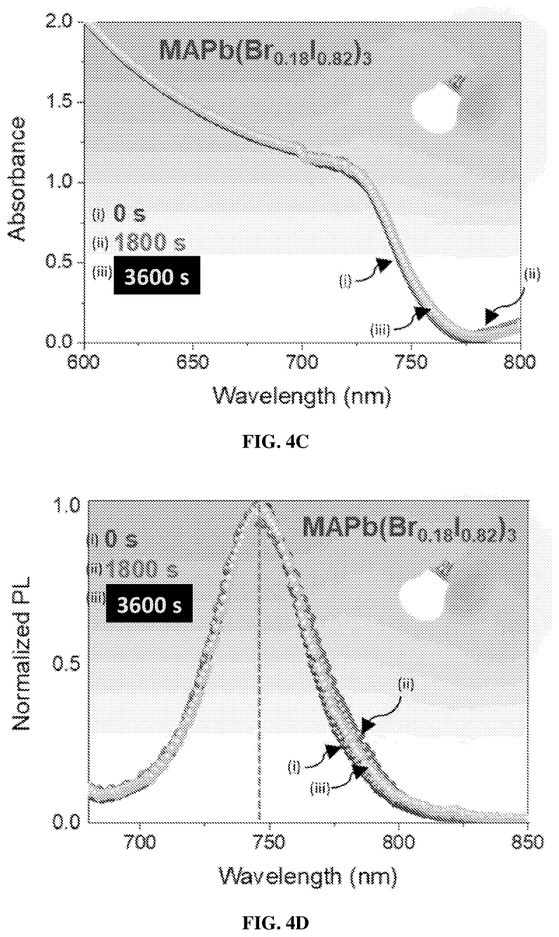

FIG. 4A and FIG. 4B show absorbance spectra photoluminescence spectra respectively of MAPbI₃ under continuous 1 sun illumination from 0 s to 3600 s as a measure of light stability, while FIG. 4C and FIG. 4D show absorbance spectra photoluminescence spectra respectively of MAPb(Br_{0.18}I_{0.82})₃ under continuous 1 sun illumination from 0 s to 3600 s as a measure of light stability. No significant variations have been observed in either the absorption and steady-state photoluminescence spectra for MAPbI₃ (FIG. 4A and FIG. 4B) and MAPb(Br_{0.18}I_{0.82})₃ (FIG. 4C and FIG. 4D) films. These results validate the photostability of both films and demonstrate the absence of halide segregation for the MAPb(Br_{0.18}I_{0.82})₃ composition.

### Perovskite Solar Cell Fabrication

Fluorine-doped tin oxide (FTO) glass substrates were cleaned using decon soap, water, and ethanol. Low-temperature bilayer p-SnO₂/PCBM was used as an electron transport layer.

The Spiro-OMeTAD (70 mg/mL in chlorobenzene) (Lumtec) was prepared with addition of 28.5 mL 4-tert-butylpyridine (Sigma Aldrich) and 17.5 mL bis(trifluoromethane)sulfonamide lithium salt (Sigma Aldrich) solution (520 mg/mL in ACN). The Spiro-OMeTAD is deposited by spin-coating at 5000 rpm for 30 s. A 100 nm gold electrode was deposited as back contact using thermal evaporation.

### PSC with Spiro-OMeTAD as Hole Transport Material (HTM)

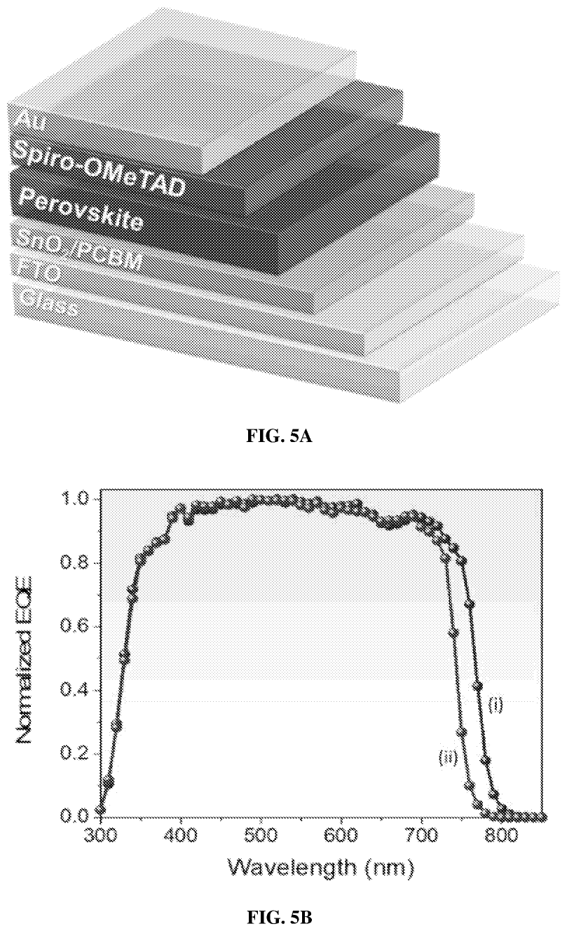

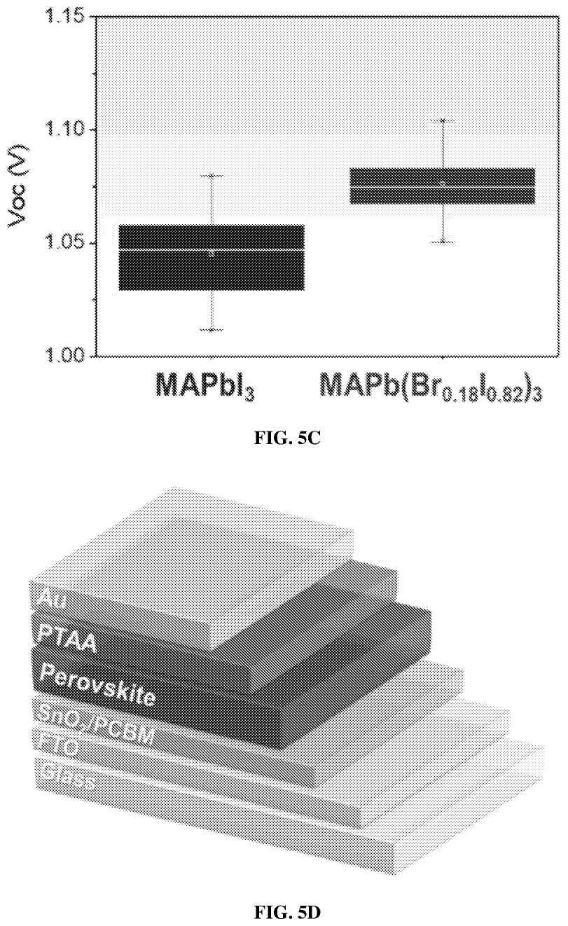

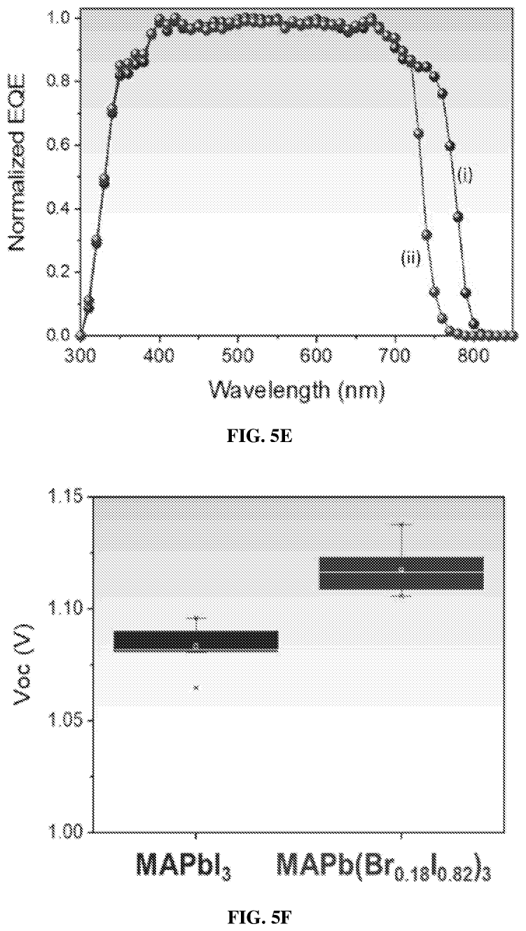

Perovskite solar cells (PSCs) based on both MAPbI₃ and MAPb(Br_{0.18}I_{0.82})₃ were fabricated in the n-i-p configuration using the bilayer SnO₂/PCBM as electron transport material (ETM) and Spiro-OMeTAD as hole transport material (HTM), and a gold top contact, as shown in FIG. 5A. As can be seen from FIG. 5B, the band edge of the external quantum efficiency (EQE) with this device structure shifted toward lower wavelengths (about 30 nm), indicating successful bandgap tuning. Consistently, the perovskite solar cells show an average increase in Voc of about 30 mV, from an average of about 1.04 to about 1.076 V, upon bromine inclusion, as shown in FIG. 5C, in agreement with the widening of the perovskite bandgap.

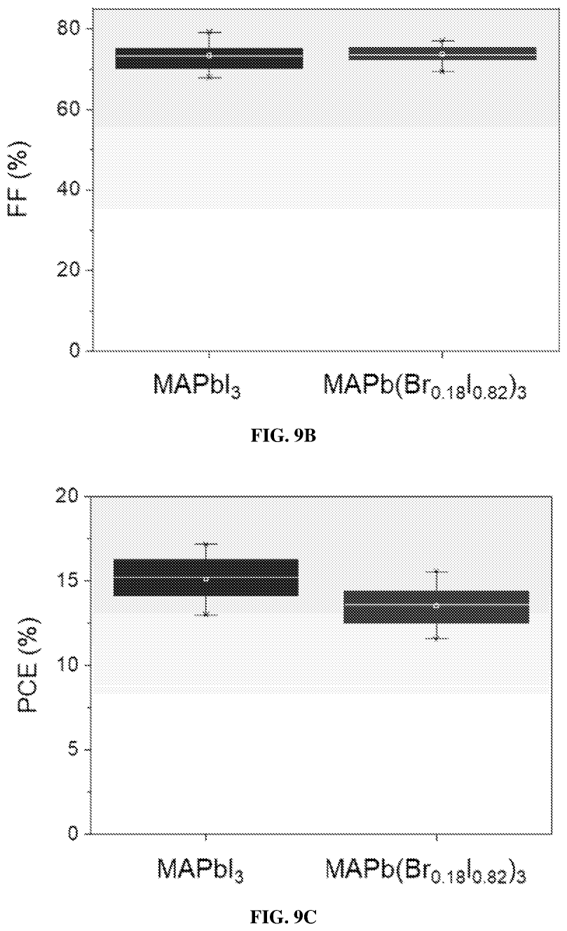

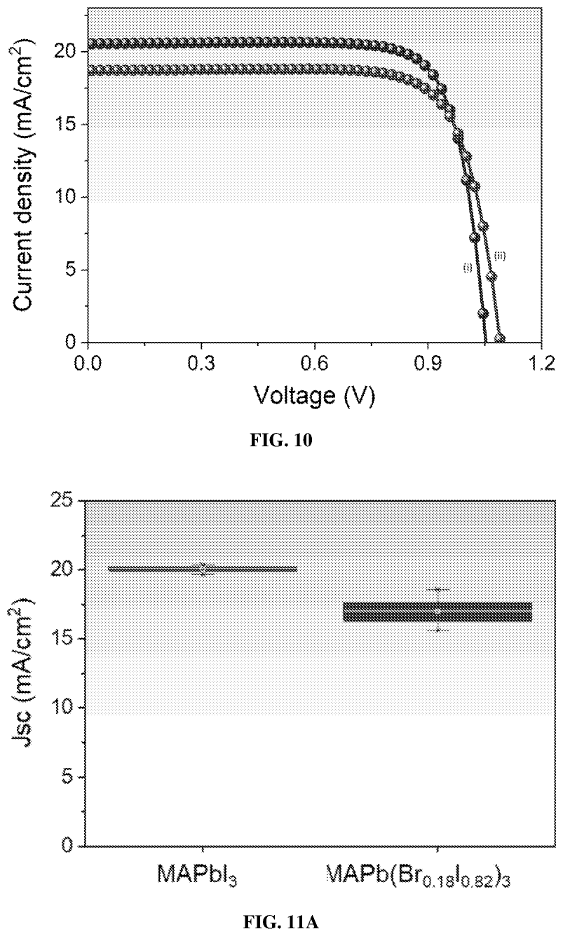

The statistical distribution of all the photovoltaic parameters (J_{sc}, FF, and PCE) are shown in FIG. 9A to FIG. 9C. The champion PSCs show PCE of 17.0% and 15.6% for MAPbI₃ and MAPb(Br_{0.18}I_{0.82})₃, respectively, as shown in FIG. 10.

### PSC with Poly(Triaryl Amine) (PTAA) as Hole Transport Material (HTM)

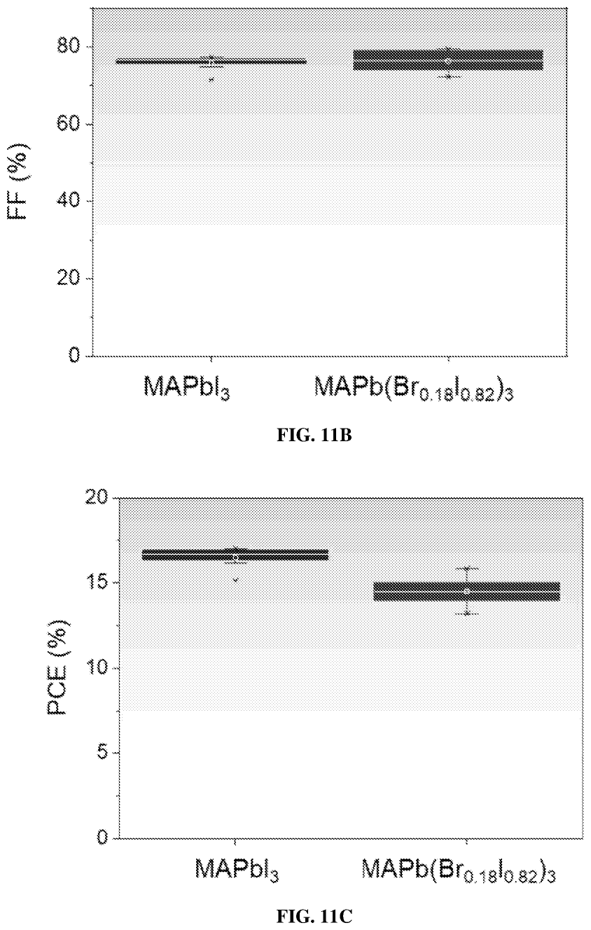

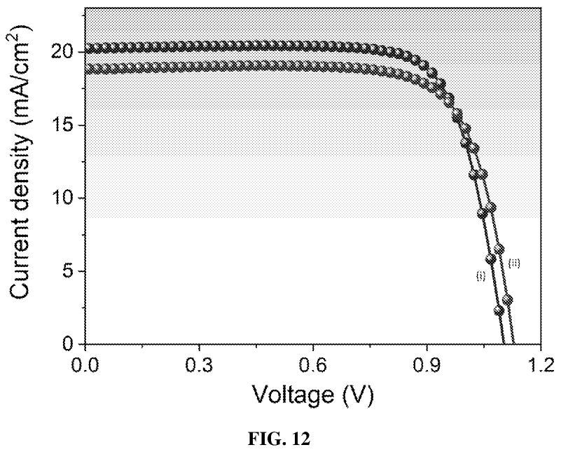

PSCs based on both MAPbI₃ and MAPb(Br_{0.18}I_{0.82})₃ with poly(triaryl amine) (PTAA) HTM were also fabricated according to the schematic diagram shown in FIG. 5D. PTAA was chosen as alternative HTM due to its higher transparency at UV-region as compared to Spiro-OMeTAD, which may be more beneficial for semi-transparent PSCs or tandem integration. A similar wavelength shift of 30 nm was observed in the EQE spectra, as can be seen from FIG. 5E. An increase in V_{oc} of about 30 mV (from 1.090 to 1.118 V) was also observed systematically, as shown in FIG. 5F. The additional photovoltaic parameters (J_{sc}, FF, and PCE), are shown in FIG. 11A to FIG. 11C. In this device configuration, the champion PSCs achieved PCEs of 17.0% and 16.0% for MAPbI₃ and MAPb(Br_{0.18}I_{0.82})₃, respectively, as shown in FIG. 12.

### Textured Substrates

One of the main advantages of the thermal co-evaporation deposition method is the possibility of conformally coating the perovskite on textured surfaces with pyramidal structures with peaks as high as 5 μm.

Polished wafers (Topsil) were textured in alkaline (KOH) solution to obtain randomly distributed pyramids. To accommodate the evaporated perovskite films, size of the pyramids was controlled with different KOH concentrations, targeting pyramid sizes in the range of 5 to 7 μm. The wafers were then cleaned with a standard RCA process. The RCA bath was formed of 5 parts water (H₂O), 1 part of 27% ammonium hydroxide (NH₄OH), 1 part of 30% hydrogen peroxide (H₂O₂). The wafers were soaked in the RCA bath at 70° C. for 15 minutes, followed thereafter by rinsing with DI water and blown dry. Clean up of the area was made and wastes disposed.

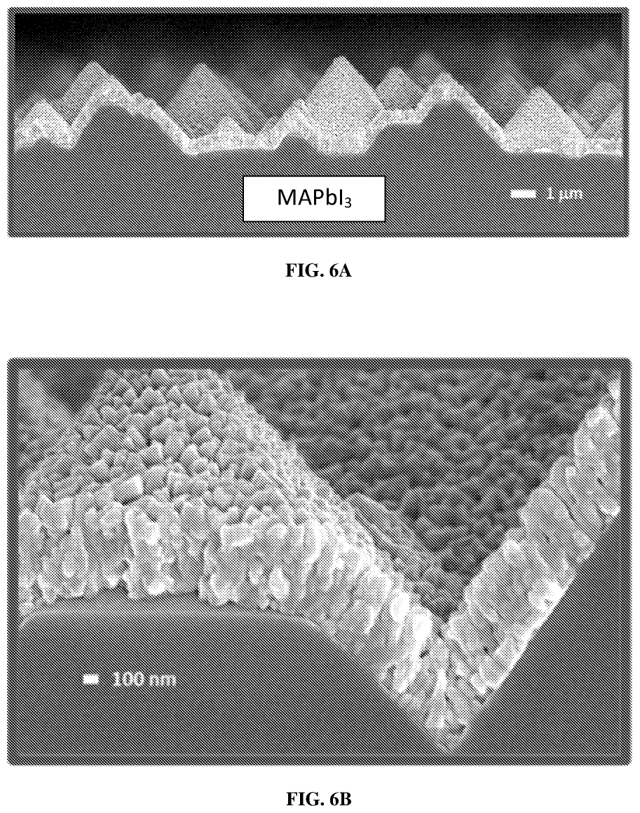

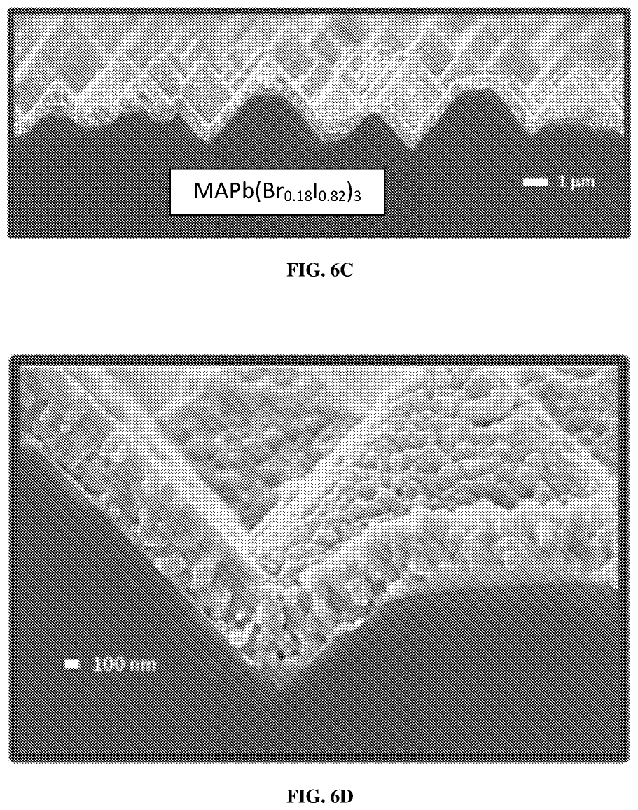

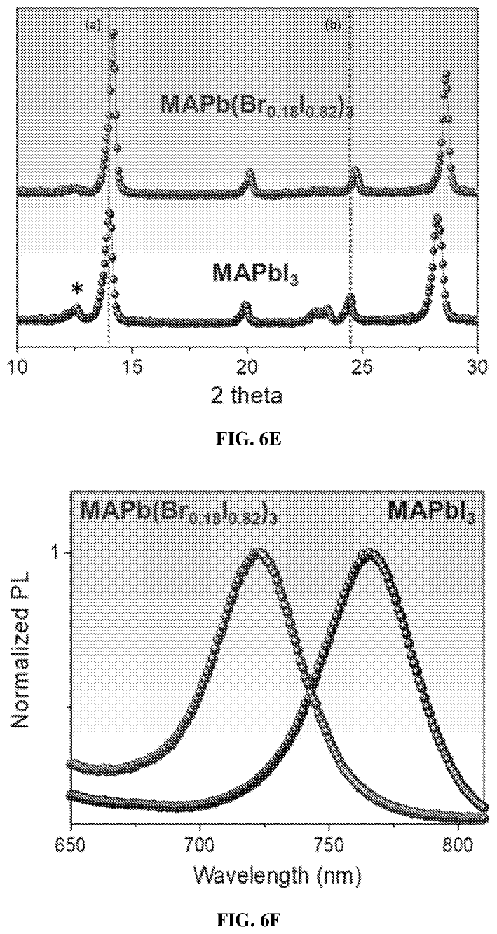

The morphological analysis based on the FESEM cross-section image shown in FIG. 6A reveals conformal coating of co-evaporated MAPbI₃ following the silicon pyramidal texturization. From the magnified view of FIG. 6B, it can be seen that the MAPbI₃ consists of uniform small grain sizes throughout the whole thickness, similarly to when deposited on a flat surface. Here, it has been demonstrated that the MABr interdiffusion method disclosed herein is efficient also when applied on textured surfaces making it promising for monolithic tandem configuration which requires high bandgap perovskites conformally deposited on textured surfaces.

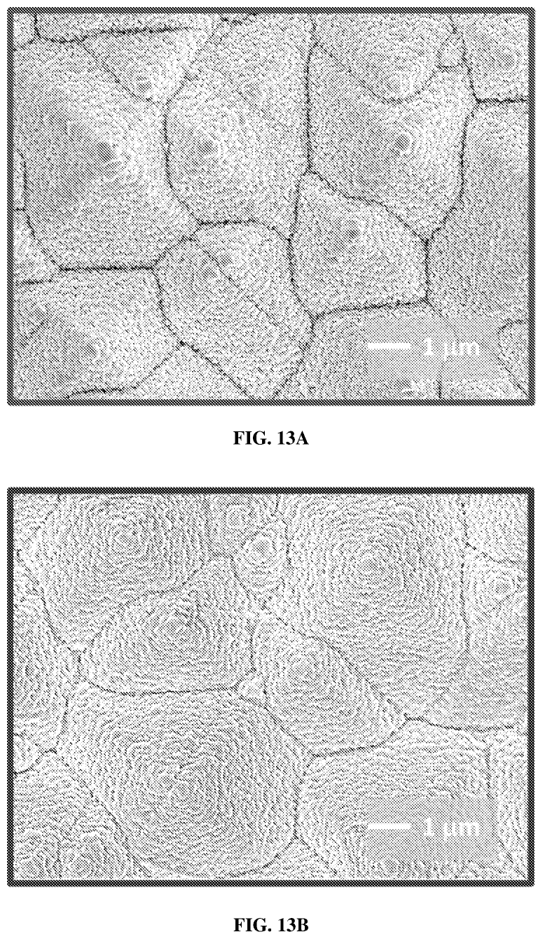

Indeed, upon the MABr treatment on the perovskite deposited on silicon, there was a negligible change on the conformal coating over the textured surface confirming that the perovskite coverage was not affected by the treatment, as can be seen from FIG. 6C. The cross-sectional morphology shows similar grain structures like the one observed on the flat surfaces with larger grains observed nearby perovskite top surface, as seen in FIG. 6D. The top view FESEM images of FIG. 13A and FIG. 13B show the complete coverage over a large area of textured silicon.

The XRD patterns of the co-evaporated MAPbI₃ and MAPb(Br_{0.18}I_{0.82})₃ over textured surfaces are shown in FIG. 6E. The deposited MAPbI₃ on the textured surface shows a more pronounced preferential orientation in the <110> direction and less amount of PbI₂ peak as compared to the material deposited on a flat substrate. This change in MAPbI₃ orientation may be related to the different behaviors of PbI₂ and MAI during the co-evaporation process, resulting in more MAI content when deposited in the textured surface as compared to the planar surface. While in the MAPb(Br_{0.18}I_{0.82})₃ film, the excess PbI₂ peak disappeared and a 0.2° peak shift was observable for both <110> and <202> perovskite orientation as compared to the MAPbI₃ counterpart, confirming the bromine inclusion based on the reaction of MABr with excess PbI₂, as can be seen from FIG. 6E.

FIG. 6F also shows the PL shift towards shorter wavelengths after the MABr treatment, consistently with what has been observed on flat surfaces. These results highlight that the halide interdiffusion method may be efficiently applied for MAPbI₃ deposited on both flat and textured surfaces.

### Characterization

Morphological characterization was recorded using a Field Emission Scanning Electron Microscope (FESEM, JEOL JSM-7600F, 5 kV, and 10 mA). The absorbance was recorded using UV-Vis-NIR Spectrophotometer (UV3600, Shimadzu). The steady photoluminescence spectra were measured by Spectro-fluorophotometer (Shimadzu, RF-5301PC). The current density-voltage (J-V) curves were measured using AM 1.5 sunlight (Newport) which is calibrated using a standard silicon solar cell. The active area of 0.086 cm² was determined by a metal shadow mask. The incident photon-to-current conversion efficiency (IPCE) was measured by using a PVE300 (Bentham), with a dual xenon/quartz halogen light source in DC mode Newport Oriel Sol3ATM solar simulator with a 450-Watt Xenon lamp. The XRD patterns of the thin films were recorded using X-ray diffraction (XRD; Bruker D8 Advance XRD).

In this work, a facile hybrid method to widening the bandgap of the co-evaporated MAPbI₃ perovskite by treating the films with a MABr solution was demonstrated. Indeed, by tuning MABr reaction time, a MAPb(Br_{0.18}I_{0.82})₃ film with a bandgap of about 1.66 eV can be obtained by using a co-evaporated MAPbI₃ as a template with a bandgap of about 1.6 eV. The n-i-p PSCs integrating MAPb(Br_{0.18}I_{0.82})₃ as the active layer and either Spiro-OMeTAD or PTAA as HTMs, showed a consistent Voc increase up to about 30 mV, as compared to the PSCs based on MAPbI₃. This method is effective for MAPbI₃ films with thicknesses well above 300 nm and deposited on both flat and textured surfaces (pyramidal heights about 5 μm), showing the potential of forming high bandgap perovskite conformally deposited for monolithic tandem integration.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

1. A method of bandgap tuning of co-evaporated perovskite by a solution process, the method comprising:
providing a co-evaporated perovskite, and
treating a surface of the co-evaporated perovskite with a halide-based solution to diffuse the halide-based solution into the co-evaporated perovskite thereby doping it with a halide dopant to form a doped co-evaporated perovskite, wherein the doped co-evaporated perovskite has a characteristic bandgap that is shifted towards a smaller wavelength as compared to the characteristic bandgap of the co-evaporated perovskite before the doping.

2. The method according to claim 1, wherein providing the co-evaporated perovskite comprises co-evaporating a first precursor compound and a second precursor compound to form their respective vapours in the presence of a substrate, and allowing the vapours to react so as to form a conformal coating of the co-evaporated perovskite on the substrate.

3. The method according to claim 2, wherein the substrate has a textured surface comprising structures each having a height in the micrometres range.

4-6. (canceled)

7. The method according to claim 2, wherein the first precursor compound is selected from the group consisting of methylammonium iodide, formamidinium iodide, cesium iodide, rubidium iodide, guanidinium (GA⁺) iodide, and phenethylammonium iodide.

8. The method according to claim 2, wherein the second precursor compound comprises lead iodide.

9. (canceled)

10. The method according to claim 1, wherein the halide-based solution is selected from the group consisting of methylammonium bromide solution and formamidinium bromide solution.

11-13. (canceled)

14. The method according to claim 1, wherein treating a surface of the co-evaporated perovskite with the halide-based solution comprises controlling the time period at which the treating is carried out to control the extent at which the characteristic bandgap is being shifted.

15. The method according to claim 1, wherein treating a surface of the co-evaporated perovskite with the halide-based solution further comprises removing excess halide-based solution after diffusion of the halide-based solution into the co-evaporated perovskite has taken place.

16. A doped co-evaporated perovskite having a tuned bandgap prepared by a method according to claim 1.

17. A doped co-evaporated perovskite having a tuned bandgap, comprising a co-evaporated perovskite doped with a halide dopant, wherein the doped co-evaporated perovskite has a characteristic bandgap that is shifted towards a smaller wavelength as compared to the characteristic bandgap of the co-evaporated perovskite without the halide dopant.

18. The doped co-evaporated perovskite according to claim 17, wherein the halide dopant has a decreasing concentration gradient along a thickness direction from a surface of the doped co-evaporated perovskite.

19. The doped co-evaporated perovskite according to claim 17, having formula AB(PₓQ₁₋ₓ)₃, wherein A represents an organic, inorganic or hybrid cation, B represents a metal cation, P and Q are different halide anions, and x is in the range from about 0.1 to about 0.5.

20. The doped co-evaporated perovskite according to claim 19, wherein A is selected from the group consisting of methylammonium, formamidinium, cesium, rubidium, guanidinium (GA⁺), phenethylammonium, and combinations thereof.

21. The doped co-evaporated perovskite according to claim 19, wherein B is lead cation.

22. The doped co-evaporated perovskite according to claim 19, wherein P and Q are independently selected from the group consisting of chloride anion, bromide anion, and iodide anion.

23. The doped co-evaporated perovskite according to claim 17, having formula CH₃NH₃Pb(Br_{0.18}I_{0.82})₃.

24. The doped co-evaporated perovskite according to claim 17, wherein the doped co-evaporated perovskite is a conformal coating positioned on a substrate.

25-27. (canceled)

28. The doped co-evaporated perovskite according to claim 17, wherein the doped co-evaporated perovskite has a decreasing grain size gradient along a thickness direction from the surface of the doped co-evaporated perovskite.

29. The doped co-evaporated perovskite according to claim 28, wherein grain size of the doped co-evaporated perovskite at an inner portion of the doped co-evaporated perovskite is about 20% to about 50% of that at a surface portion of the doped co-evaporated perovskite.

30. A solar cell comprising:
a doped co-evaporated perovskite having a tuned bandgap,
(a) prepared by a method comprising providing a co-evaporated perovskite, and treating a surface of the co-evaporated perovskite with a halide-based solution to diffuse the halide-based solution into the co-evaporated perovskite thereby doping it with a halide dopant to form a doped co-evaporated perovskite, wherein the doped co-evaporated perovskite has a characteristic bandgap that is shifted towards a smaller wavelength as compared to the characteristic bandgap of the co-evaporated perovskite before the doping, or
(b) comprising a co-evaporated perovskite doped with a halide dopant, wherein the doped co-evaporated perovskite has a characteristic bandgap that is shifted towards a smaller wavelength as compared to the characteristic bandgap of the co-evaporated perovskite without the halide dopant;
one or more charge transport layers on a first side of the doped co-evaporated perovskite having a tuned bandgap;
one or more charge transport layers on a second side of the doped co-evaporated perovskite having a tuned bandgap opposite the first side;
a first electrode in electrical connection with the one or more charge transport layers; and a second electrode in electrical connection with the one or more charge transport layers.
